(19) United States
(12) Patent Application Publication
(10) Pub. No.: US 2024/0421634 A1
(43) Pub. Date: Dec. 19, 2024

(54) ROTATABLE TRANSMITTER PADDLE AND PADDLE RECEIVER HOUSING FOR WIRELESS POWER TRANSFER

(71) Applicant: CYNETIC DESIGNS LTD., Kelowna (CA)

(72) Inventor: Roger John SOAR, Kelowna (CA)

(21) Appl. No.: 18/735,577

(22) Filed: Jun. 6, 2024

Related U.S. Application Data
(60) Provisional application No. 63/471,310, filed on Jun. 6, 2023.

(51) Int. Cl. H02J 50/00; H01F 27/02; H02J 50/12; H02J 50/80; H05K 5/02

(52) U.S. Cl. CPC H02J 50/005; H01F 27/02; H02J 50/12; H02J 50/80; H05K 5/0221

(57) ABSTRACT

A rotatable paddle wireless power transfer system provides a robust electric power and data connection between a user and a support vehicle or structure adapted for use in harsh environments. A paddle retention clamp such as a pair of sprung circumferential fingers coupled on either side of a gap into a paddle retainer allows the paddle to be easily removably inserted by a user into the retainer, for example with only a single heavily gloved hand. When the paddle is docked in the paddle retainer, the paddle may be easily rotated relative to the retainer, with up to 90 degrees of rotational freedom so as to provide a non-binding disconnect of the paddle from the paddle retainer during normal or emergency disconnects through 360 degrees of force applied by the user to an electrical umbilical cable affixed to the paddle.

### FIELD

This invention relates to the field of wireless transmission and reception of power using couplings designed for ease of coupling and uncoupling in environments benefiting from one-handed operation.

### BACKGROUND

Most modern warfighter systems utilise a high-capacity battery as its central power source. The battery can be of multiple form factors. Typical form factors are the low thickness, large area battery such as the Conformal Wearable Battery (CWB¹) that can be inserted into a tactical vest hard armour plate pocket and, the more cubic form factor Small Tactical Universal Battery (STUB). The warfighter battery power source provides power to a variety of wearable electronic devices that the warfighter carries such as radios, GPS device, enhanced vision devices, auxiliary rechargeable batteries, flashlights, powered environmental clothing or an end user device such as a handheld portable computer or cell phone type device, as some examples. With the increasing number of peripheral electronic devices and increasing power demands, today's warfighter must be able to optimise their individual power planning.

For the most part, the following description of, and claims to, various formats of a wireless power transfer paddle system, hereinafter the paddle system, will be discussed within a military use context. Although it is envisioned that the paddle system transmitter (TX) and Receiver (RX) will find most application within that environment, there may also be other applications, such as outer-space applications, and within civilian applications such as used by police, fire, search and rescue; commercial applications such as in construction and surveying, industrial applications within forestry, oil and gas exploration applications and recreational applications for example. In addition, the paddle system can be used on battery powered electronic equipment and devices that need to be sealed from the environment but would benefit from external battery recharge or data transfer such as marine and underwater applications.

Before a warfighter goes out on a mission the central battery(ies) of a warfighter system is charged using a charging adaptor or charging dock that may receive its power from a variety of ACV and DCV power sources. As power is consumed during a mission by the warfighter system electronic devices, the warfighter must maintain and optimise the warfighter's battery power levels to have an optimally functioning warfighter system.

The ability for a warfighter to obtain charge for the central battery while on-mission can be difficult as both the infrastructure and ability to remove or even swap out batteries while on-mission may be infrequent or simply impossible to do so safely when in combat situations. On-mission power logistic plans for the warfighter must allow for the warfighter to take advantage of charging opportunities that readily present themselves, to maintain their central system battery at optimal charge levels and therefore have the electronic devices being carried available for use.

As maintaining a warfighter's central battery is critical to the performance and function of the warfighter system, it becomes imperative that a warfighter be able to obtain or scavenge power whenever an opportunistic situation presents. The most prevalent opportunity to secure opportunistic power is when the warfighter is seated in a mobile platform such as a land vehicle, maritime vessel, submarine, aircraft or spacecraft, hereinafter generically referred to as a vehicle. On many occasions the warfighter may only be seated on or within the vehicle for a short period of time, so it is crucial that the warfighter be able to access as much power in as short a time period as possible.

When seated in a vehicle or other structure, power and data is available from the vehicle power and data bus via direct connection using a conventional electro-mechanical connector and cable or by using wireless power transfer.

A wireless power connection enables the warfighter system to connect to the vehicle power bus without the use of a conventional electro-mechanical connector. The warfighter system power manager ports the received wireless power to a battery charger which in turn would charge the warfighter system central battery or batteries. Wireless power systems provide the ability to transfer power in extreme or austere environments that would present contamination, fouling or corrosion issues for conventional electro-mechanical connectors.

A wireless power transfer system is defined as any system where electrical power is transmitted from a power source to an electrical load without interconnecting wires. The power can be transferred across a gap such as an air-filled gap or water filled gap, or through non-conducting materials or combinations of the above.

The paddle system provides electric power and data to an independent warfighter system power and data manager that in turn provides power and data to the warfighter's system devices which may include a discrete Li battery charger that will the provide charge power to the warfighter central battery.

The charging rates for Lithium (Li) batteries and for the transmission of wireless power within the context of this disclosure are rated as follows: Low power means less than 30 watts (W); medium power is less than 100 W; high power is greater than 100 W. Its is expected that the paddle system will be capable of servicing and providing power into all warfighter system power level requirements up to and including 400 W.

A further application of the paddle system is for both commercial and military combat diver or underwater operators who are presented with the difficult task of managing individual power planning while working underwater. Divers have an increasing number of electronic devices requiring power while at the same time they must be able to reduce their dependency on a finite power supply regardless of a changing dive or mission scenario. A principal method to obviate much of this concern is for the diver to be able to connect and disconnect at will to undersea vehicle power and data. In addition, any subsea related portable equipment that has a recharge capability, benefits if it can be quickly connected via the paddle system to an undersea vehicle.

Traditionally, undersea connections are made using industry standard wet mate able connectors, however this type of connector has operational drawbacks that need to be addressed for increased operator efficiency and effectiveness. The paddle and paddle retainer of the paddle system meets or exceeds the needs of sub-surface environmental conditions by a sub-surface diving environment. Through the application of wireless power transfer and close proximity radio transceivers, a contactless connector is possible that eliminates many of the operational problems inherent in a wet mating electro-mechanical contact connector.

Reliability of the power and data connection is of paramount concern to the underwater operator as a wet mating connector is easily fouled by sand, debris or biofouling and typically if a connector is not to be used a dummy connector or protective cap must be used to protect the exposed connector contacts. Over time, exposed connector contacts may be corroded by saltwater and great care must be used in overall maintenance of the connectors which typically are only rated for five hundred underwater mating cycles. Due to the insertion pressures and pin alignment requirements to make the wet mating connection an operator must frequently use both hands to connect the two inline mating connector components.

In the paddle system, TX paddle and RX retainer housings may be ruggedized to operate at depths greater than 30 m to transfer power over thousands of connection cycles.

Applicant's inductive power transfer systems currently provide both the ability to transfer up to 200 W (400 W future) of electrical power and medium rate bi-directional RF data between an undersea vehicle and a combat diver, enabling high-capacity charging of a diver system central battery, without the use of a conventional electro-mechanical connector and data transfer from and to the vehicle.

A further application is the use of the paddle by an astronaut in space. The retainer would be placed on an astronauts Extravehicular Mobility Unit (EMU) or space suit and the paddle system TX paddle can be located within interior locations, such as but not limited to, an airlock in a space station or space capsule, on external surfaces such as exterior loading docks and maintenance areas or on external equipment such as or similar in function to a robotic arm, as an example the Canadarm®, that can support or carry an astronaut while conducting extravehicular activities. For interior locations that provide egress to outer space, i.e. an airlock, the intent of the inductive paddle remains the same: providing power in a hostile environment to a user encumbered by heavy equipment; with limited line of sight; while the user is wearing heavy gloves; and, that provides a quick egress capability without having to purposely disconnect. Within interior locations that provide egress to outer space, the wireless power connection provides a further advantageous function in that it is inherently safe for use in an explosive environment, as it will not produce a spark when a power transfer connection is made or broken. This enhances safety in the potentially explosive oxygen rich environment that may be experienced within a space vehicle. During extravehicular activities, the paddle system would provide makeup power to the astronauts EMU to charge onboard batteries, increasing reserve capacity for life support and suit accessory equipment. A wireless power connector would in general provide ease of use by a heavily gloved astronaut versus conventional electrical connectors presently used in space.

On space applications that take place on lunar or planetary surfaces, for example the moon or Mars, wireless power transfer as on earth applications using the paddle system may be used when an astronaut is seated in a rover or over ground vehicle, providing power transfer between the vehicle and the astronauts space suit. In addition, other ground vehicles requiring a human operator such as construction equipment i.e. excavator, earth movers and cranes for example would provide a suitable vehicle/operator interface for the application of the inductive power transfer by the paddle system to the operator.

### SUMMARY

The paddle system according to the present disclosure for wireless power transfer includes a paddle retainer on a first surface of a receiver coil housing and a paddle having a transmitter coil housing. The transmitter coil housing has a first planar surface which has a circular perimeter, and the paddle has a circular rim coinciding with the circular perimeter. The rim has a first thickness. The paddle retainer includes at least segments of an annular channel around a perimeter of the first surface of the receiver coil housing. The annular channel is adapted to mate in sliding relation with the rim of the paddle when the first planar surface of the transmitter coil housing is parallel with, and immediately adjacent to, the first planar surface of the receiver coil housing. The annular channel has a gap through which the paddle is inserted so as to releasably mate with the annular channel. The system also includes at least one resilient clamp mounted at the gap of the annular channel and arranged to resiliently urge the paddle into mating engagement with the annular channel and to resiliently hold the rim of the paddle in the annular channel once the paddle has been inserted through the gap so as to mate the rim of the paddle with the annular channel.

In another aspect, the at least one resilient clamp may be a pair of resilient clamps, and the gap in the annular channel has first and second edges, and one clamp of the pair of resilient clamps is mounted on each of the first and second edges.

In another aspect, the pair of resilient clamps may include resilient clamps chosen from the group comprising: sprung fingers, spring arms, rigid arms biased by a spring, any combination of these. In another aspect, each of the resilient clamps of the pair of resilient clamps may be elongate and may have a base end and an opposite free end. In this aspect, the base end of a first clamp of the pair of resilient clamps is mounted to the first edge of the gap into the annular channel so as to position the free end of the first clamp over, so as to partly occlude the gap into the annular channel, and the base end of a second clamp of the pair of resilient clamps is mounted to the second edge of the gap into the annular channel so as to position the free end of the second clamp over, so as to partly occlude the gap into the annular channel. The first and second clamps are opposed-facing.

In another aspect, the gap into the annular channel spans 120 degrees arc relative to a center of curvature of the annular channel.

In another aspect, the annular channel is sized to snugly accept the rim of the paddle in sliding mating therein contiguously around an entire length of the annular channel.

In another aspect, the annular channel has drainage apertures formed therein.

In another aspect, the annular channel is segmented to facilitate drainage of fluid from the annular channel.

In another aspect, the segments of the annular channel are chosen from the group comprising multiple fingers, projections or clips arranged around the periphery of the retainer and adapted to retain and secure the paddle within the retainer.

In another aspect, a paddle umbilical cable is integrally formed with and electrically coupled to a TX drive housing within the paddle.

In another aspect, the umbilical cable further includes, so as to pass through, a resilient cable strain relief attached to the paddle, and wherein the strain relief is adapted to facilitate ejection of the paddle from the paddle retainer.

In another aspect, the paddle retainer is such that the paddle is ejected from the annular channel when a tension force is applied so as to pull the paddle out of the plane of the paddle and receiver housing.

In another aspect, the TX and RX coils are chosen from the group comprising wound with single conductor wire, multiconductor wire structures, litz wire structures or stacked printed circuit board coil structures.

In another aspect, the coil is a multi-layer self-resonant structure, where the coil is constructed from multiple layers of foil that are layered between a non-conductive substrate or dielectric material.

In another aspect, the gap is adapted so that the paddle is rotatable through an arc of 90 degrees while retained within the annular channel of the retainer.

In another aspect, the paddle system is adapted to be used in terrestrial vehicles, fixed structures on land, submersible vehicles, aeronautical vehicles, or space vehicles.

In another aspect, the paddle system is adapted to transfer electrical power and data between the vehicles or fixed structures to human operators or to electronic devices and equipment.

### BRIEF DESCRIPTION OF THE DRAWINGS

In the accompanying Figures, like reference numerals denote corresponding parts in each view, and wherein:

FIG. 1. Shows the principal components of the wireless power transfer system which includes the TX drive electronics housing that provides the drive signal to the TX paddle which is inserted into the RX retainer. When the TX paddle is inserted into the RX retainer, power is transmitted and data transmitted and received from the TX paddle to RX retainer for the charging of batteries carried by a system user or a device the system is incorporated onto. Transmitted and received data can be used as required by the users system or a remote electronic device.

FIGS. 2A and 2B show two variants of TX umbilical cable type that may be implemented on the power and data system.

FIGS. 3A and 3B show one of many configurations for a motorised or mechanically sprung, retractable TX umbilical cable and TX paddle using a cable reel housing.

FIG. 4. An illustration of an early design concept during development of the TX paddle planar coil system, showing a TX paddle with a principally square or rectangular shape that is inserted into the RX receiver that has a square or rectangular TX paddle retainer, designed to accept the rectangular TX paddle.

FIG. 5. Detail of the external features of the circular TX paddle and RX retainer with a conventional connector that is used to connect to a user electrical system.

FIG. 6. An overview cross section of the TX paddle placed beside the RX retainer.

FIG. 7. A detailed cross section of the TX paddle inserted into the RX retainer showing proximal location of related components.

FIGS. 8A through 8D illustrate the displacement mechanics of the RX retainer circumferential retention clamps or fingers.

FIGS. 9A through 9C show the shows the angular rotation capability of the TX paddle when docked within the RX retainer.

FIG. 10. shows how the TX paddle can be removed from the RX retainer while in any angular orientation within the 90-degree arc of free paddle rotation that is provided when the TX paddle is docked in the RX retainer.

FIGS. 11A to 11C illustrate what happens when a force is applied to the TX umbilical cable of a docked TX paddle in a direction that is 180 degrees opposed to the gap of the RX retainer. This event may occur in an emergency or accident or other equipment usage scenario so that the TX paddle does not hang up or bind within the RX retainer and impede either the emergency egress from a vehicle of the user or in the application of other equipment, the separation of the TX paddle from the RX retainer. The RX retainer therefore provides release of the TX paddle through 360 degrees of applied force to the TX umbilical cable.

FIGS. 12A through 12C shows three additional configurations of a sprung arm retention clamp that could be used to retain the TX paddle within the RX retainer.

FIG. 13. The TX paddle is illustrated with the cover removed to show alternate locations and types of radio transceiver module antennas that can be located within the paddle.

### DETAILED DESCRIPTION

The wireless power transfer system, which includes a paddle and paddle retainer, is comprised of three components. Wireless power transmission (TX) drive electronics, located within a TX drive housing, provide the wireless power signal to the TX paddle. The TX paddle, hereinafter referred to as the TX paddle or paddle, is connected by an electrical power and data transfer umbilical cable, hereinafter referred to as an umbilical cable, to the TX drive housing. The TX paddle is inserted into the paddle RX retainer. The paddle retainer wirelessly receives the wireless power transmitted by the paddle, and thus is designated as the RX receiver retainer or RX retainer. The RX retainer mechanically receives and mates with the TX paddle. Both the TX paddle and RX retainer contain coils to transmit and receive wireless power respectively. The RX retainer contains the electronic circuits that rectify the AC wireless power received from the TX paddle and provides the rectified AC signal as DC power to the user's power system, through a power and data input connector socket or cable with attached connector. As well as transmitting wireless power, the paddle system can also provide wireless data transfer using radio module transceivers embedded within the paddle system allowing both the transmission of and reception of data between the user's data manager or components and the vehicle data system. RF data can be provided for example using RF transceivers located within each of the TX drive housing and the RX retainer. Antennas for the RF transceivers are located with the TX paddle and adjacent to the RX coil so that the RF transceiver antennas are co-located when the TX paddle is docked, as described below, in the RX retainer. RF transceivers could operate using, but not be limited to Wi-Fi®, ZigBee®, Bluetooth®, Z-Wave®, UWB® RF or NFC® technologies that are licensed or unlicensed including those operating in the Industrial, Science and Medical Bands. The data can be used among other applications on user tactical computers, radio and image transmission, Blue force tracking or generic data exchange and may be encrypted or unencrypted.

Narrow band operational frequencies can be selected for either the power or RF transceiver so there is no interference between the two. For example, 100 kHz power transmission frequencies do not have any impact upon the signal quality of an UWB transceiver module operating at 5 GHZ, likewise magnetic resonance operating at 6 MHz would have little if any impact on a RF device operating at 2.5 GHz or higher.

The TX drive housing may for example be made of a diecast, machined metal or structural polymer that provides physical and environmental protection to the TX electronic drive circuits. Direct Current Voltage (DCV) and data from a vehicle, structure or other external sources power and data bus is provided to the TX drive unit via a power and data cable which is connected to the TX drive with a bulkhead connector or using a pass-through cable gland. A low resistance electrical and data umbilical cable, the TX umbilical cable, exits the TX drive housing via a sealed cable gland that extends to the TX coil. The TX coil is encased by the TX paddle housing which provides mechanical and environmental protection to the TX coil as well as providing the physical shape for it to engage and be inserted into the RX retainer. The TX coil paddle housing advantageously is a polymeric material so as not to interfere with transmission of the magnetic field transmitted from the TX coil to the RX coil. The TX paddle housing is environmentally sealed. The length of the TX umbilical cable is determined by the vehicle application and is typically, but not limited to, lengths between 12 and 72 inches. The longer the cable the greater the cable resistance to the TX drive signal which lowers the overall wireless power transfer efficiency. The TX paddle may have a low-profile and provide a cable entry for the umbilical cable into the paddle via an over molded feature or may have a higher profile with the umbilical cable entry into the paddle via a threaded or mechanically attached cable gland, which may be of several types but preferably a pigtail or flexible gland that acts as a cable strain relief.

In many applications, the TX umbilical cable between the RX drive housing and the TX paddle will be a straight form, robust, extruded cable which may be constructed to be compliant so that it conforms resiliently to gentle or severe bends along its length, due to force applied by the user. For lengths longer than 72 inches the umbilical cable may for example be constructed as a formed retractable, coiled or spring like cable such as that used on radio handsets. Such a cable can be stretched up to three to five times longer than its nominal unstretched length and then return back to its nominal coiled length after use.

If it is required that the TX umbilical cable be completely stowed between uses, umbilical cable may be wound around a reel capable of deploying and retracting the cable. There are several options for the configuration of a cable reel. It may be operated manually with the cable retracted by manually turning the reel; using a spring tensioned reel that employs a ratchet or similar holding mechanism to lock the cable at the desired length of deployment, as is frequently found on hose or electrical cable reels; or, the cable reel may be powered by an electric motor, internal to the reel housing, that can be controlled to either deploy or retract the TX umbilical cable. At anytime the user can decide to extend the length of the umbilical cable or retract the umbilical cable and paddle back into the housing when the power transfer function is no longer required. By employing the retractable TX umbilical cable, a long TX umbilical cable is protected by the reel housing when not in use and a potential trip or other interference hazards are eliminated when the TX paddle is not in use. The retractable reel assembly would be comprised of a cable reel housing containing either a manually, mechanically sprung, or electric motor operated cable reel that contains a length of TX cable terminated by the TX paddle. The TX drive electronics can be either co-located within the housing or be remotely located with the TX drive output signal connected to the TX cable via power and data slip rings, that are aligned concentrically with the central axis of the cable reel. The entire system may still retain all environmental and submersible features by employing sealed slip rings and placing the TX drive and data circuits in a sealed compartment within the reel housing.

If required, the power transfer system can be designed as a central hub with for example, but not limited to, four integrated TX drive systems ported to the umbilical cables of four TX paddles.

The paddle system RX retainer housing may be comprised of two principal parts: a front polymeric structure and a rear metallic structure. The front RX retainer is advantageously a polymeric material so as not to interfere with transmission of the magnetic field transmitted from the TX coil to the RX coil. The front retainer also secures and retains the TX paddle in an optimal alignment with the RX coil. The retainer ensures the TX paddle coil remains parallel to, in alignment with, and adjacent the RX coil within a structure that provides rotational freedom of the paddle relative to the retainer about an axis of rotation which is orthogonal to the parallel planes containing the TX paddle and RX coils. The paddle is held removably secure in the RX retainer by at least one resilient clamp which resiliently urges the paddle into the retainer. The resilient clamp provides a prescribed securing or clamping force ensuring the paddle is retained in the retainer during normal movement by the user. The RX coil is located on the back side of the RX retainer face and in turn the RX coil is connected to the RX rectification circuits. The TX paddle retainer is advantageously also the cover or lid to the RX rear electronics housing. The two parts are mechanically secured together with an incorporated environmental seal. Many types of conventional attachment and sealing a cover to a housing such as screws and elastomeric seal, chemical bonding, adhesive bonding, or ultrasonic welding among other techniques may be used to join and seal the RX retainer.

The RX rectification circuits are within the retainer rear housing which is manufactured from a metallic or other suitable material capable of heat transfer, which allows dissipation of heat generated by the rectification circuit to the outside environment.

Output from the RX rectification circuits to the external electrical load is typically provided via a short cable terminated with a cylindrical connector, such as the NETT warrior or MightyMouse™ connector but any user specified connector or connector on a cable may be used to connect to the soldier system or other user carried devices or batteries. The RX retainer DC power output cable exits the RX retainer housing through a bushing or sealed cable gland that may be a straight pass through gland or a gland where the cable exits at an angle to the entry.

The paddle system evolved through an iterative process that initially examined the application of round coils with a square ferrite backing, giving the paddle a nominally square or rectangular shape. It was determined that the square paddle introduced several negative features to the application of the paddle design. Even with large, rounded corners on the square paddle, the square paddle usually must be perfectly aligned to be inserted into the RX retainer otherwise the paddle would bind. Similarly, a square paddle will bind or lock if an attempt was made to withdraw the paddle with any rotational torque placed on the cable as this would cock or place an angular lock on the paddle within the RX retainer. For example, if a user performed an emergency seat egress with no prior manual separation of the TX paddle from the RX retainer, the paddle would likely lock within the retainer with sufficient force that the user would be restrained from leaving the seat. From a military or police user perspective this is unacceptable and an alternative geometry that would not bind the two components had to be identified.

A round paddle was subsequently developed, which provided multiple advantages over the square paddle. As used herein, the description of the TX paddle, which may be generally planar, as being round or circular is not intended to imply that the paddle is perfectly mathematically circular or round. Rather, the paddle disclosed and described herein as being circular or round is intended to include being substantially circular or round, or slightly out-of-round so long as the paddle still functions as described herein for ease of removing or inserting the paddle from or inserting the paddle into the retainer without binding. The degree to which the paddle may be out-of-round and still properly function as described herein may for example depend on the tolerances of the snug fit of the paddle in the retainer. Therefore, the paddle may have an oval or elliptical shape and not be perfectly round and still function as intended due to a peripheral curvature that still provides rotational and release capability. Applicant postulates that a more loose fit of the paddle in the retainer may work almost as well for wireless power transfer as a tight tolerance, very snug fit of the paddle in the retainer, and is such a case the paddle may be slightly out of round and still may be removed out of the retainer through the resilient clamp or, if more than one, the resilient clamps retaining the paddle in the retainer. During an extraction event of the paddle from the retainer, at the point that the maximum diameter of the paddle exits through the retaining fingers the paddle will ‘pop’ out of the retainer as the retaining fingers continue to bear down on the curvature of the reducing paddle diameter.

A round paddle, as round is defined immediately above, rotates out of the retainer even when it is at the limit of its angular rotation. An edge, better described below, of the retainer acts as a pivot so that the paddle rotates around the edge and thereby slips out of the retainer. Pivoting or rotation of the paddle within the retainer allows the paddle to move when the angle or orientation of the TX paddle cable is changed relative to its normal orientation extended more or less directly away from the paddle. This movement may happen when the user moves for example within a seat or when the TX paddle is inserted or removed from the RX retainer. Allowing the TX paddle to rotate within the retainer alleviates bending strain on the cable at the cable's entry point to the paddle and also allows a greater degree of freedom in the approach angle of the TX paddle versus a square paddle when it is inserted into the RX retainer.

Ultimately a square ferrite can be used within a circular TX paddle structure, but the size of the TX circular housing is either larger to accommodate the corners of the square or the ferrite has to be made smaller to fit within the circular structure of the TX paddle, which in turn diminishes the optimal dimensions for power transfer efficiency.

The umbilical cable gland entry into the paddle may be a short waterproof cable gland or advantageously it may be a cable gland with integral strain relief. The strain relief may be a flexible extrusion such as a flexible tube or it may be a complex shape such as a pigtail strain relief. It has been found that the length of the strain relief should be between 50-100% of the paddle diameter. The combination of the strain relief length coupled with its resilience assist in the sprung release of the paddle from the retainer channel fingers allowing the paddle to be ‘popped’ out of the retainer.

The paddle system receiver housing is, in one preferred embodiment, and not intended to be limiting, comprised of two parts. The electronics enclosure, which may be within a cup, which is sealed from the environment, and the RX retainer or retainer for the circular paddle. The electronics enclosure cup may be constructed from any type of polymer or metal. The RX retainer may, as described below, include a lid made from non-conductive polymers. The lid cannot be made from conductive materials such as metals or carbon fibre re-enforced polymers as these materials will intercept and absorb the magnetic field of the TX coil and prevent efficient wireless power transfer to the RX coil.

In embodiments where the RX electronics enclosure is round, the enclosure may be sealed from the external environment with an O-ring seal between the polymer RX retainer and the metallic rear cup or housing, allowing the RX retainer to accommodate being submerged for extended periods at up to 3.3 ft (1 m) of water depth and meet the IP68² waterproofing standard. For submersed applications on combat divers or on subsea equipment or devices, depths to greater than 98.5 ft (30 m) are achieved with the appropriate mechanical packaging. The paddle system magnetic field and the wireless data transmission are unaffected by water pressure and operate as if they are on dry land over the short transmit distance required. Ultra Wide Band RF signals for example are unaffected by a water path transmission of 0.080-0.20″ (2-5 mm) but start to degrade over water path of greater than 0.4″ (1 cm).

The RX retainer may in one preferred embodiment, again not intended to be limiting, as better described below and as illustrated, have an annular channel formed as a flange around the perimeter of the electronics enclosure that acts as a retainer and retains the paddle within the retainer. A break in the otherwise annular channel forms a gap into and along the plane containing the channel so that when the paddle is inserted through the gap, in the plane of the channel, the paddle may be slid over the electronics enclosure so as to mate the rim of the paddle into the channel. The gap of the annular channel in the plane containing the channel may, advantageously, be at least as wide as the diameter of the paddle, assuming paddle to be round or substantially round, so that the paddle may snugly slide through the gap in the plane of the channel. In the embodiment where both the paddle and the electronics enclosure are round, it is informative to specify the size of the gap in terms of the number of degrees swept out by a radius from the center of the electronics enclosure, in the plane of the channel. Thus, in one preferred embodiment, not intended to be limiting, the radius sweeps out 120 degrees across the TX paddle insertion gap. That size of gap allows the circular TX paddle to be pushed into the retainer over and along the plane of the channel into mating engagement within the channel. Preferably the rim or peripheral edge of the paddle is a snug or somewhat snug fit in the channel. Advantageously the channel has two walls forming the flange of the channel, wherein one wall may be the surface of the electronics enclosure and the other wall formed as part of the channel, so that in cross section the channel forms a U-shape. The gap into the channel faces the center of the surface of electronics enclosure over which the paddle is slid as the rim of the paddle slides into the channel, preferably so that the rim of the paddle abuts the circumferential outermost wall of the channel. In preferred embodiments the paddle, once mated into the channel, is held, resiliently, in the channel by one or more resilient clamps on one or both sides of the gap into the channel. For example, and as better described below, the resilient clamps may be an opposed-facing pair of sprung retaining fingers. Other non limiting examples of types of resilient clamps are described below and illustrated in the Figures. The inside diameter of the TX paddle receiving channel is slightly larger than the diameter of the paddle, which though holding the paddle snugly in the channel, allows the paddle to rotate freely within, and relative to, the channel, where it is understood the rotation of the paddle is in a plane coplanar with or parallel to the plane containing the channel. The retainer has a flange at 90 degrees to the outside wall of the retainer that holds the TX paddle coil face against the RX retainer coil face minimising the air gap between the two faces to optimise wireless power and RF data transfer efficiencies, but with sufficient interstitial gaps to allow the paddle to rotate freely within the 90 degrees of rotation allowed by the spring arms. Where a channel is referred to on the retainer, the channel is not limited to a single point discontinuous flange it may be constructed using alternate configurations. One example of an alternate configuration is that the paddle retaining element is segmented or comprised of a series of discrete elements such as multiple fingers, projections or clips with suitable geometry and organised around the periphery of the retainer so as to retain and secure the paddle within the retainer.

The height of the channel flange above the retainer coil surface shall be dimensioned so that it allows the thickness of the paddle rim to fit within it and allow free rotation of the paddle within the retainer. The preferable minimum difference between the height of the flange and the thickness of the paddle rim should be approximately 0.004″ (0.1 mm), the preferable maximum difference between the should be 0.12-0.16″ (3-4 mm).

The round TX paddle retainer is held within the retainer by two opposed sprung circumferential fingers that act as retaining clamps to hold the TX paddle within the retainer, with a predetermined extraction force. The fingers are located on the leading edge of the 120 degree gap of the RX retainer. The purpose of the fingers is to provide a predictable or set amount of withdrawal resistance of the TX from the retainer, but that once the extraction force limit is reached, neither the fingers nor retainer bind the TX paddle within the RX retainer. The extraction force of the TX paddle from the retainer is determined by the force required to displace the sprung fingers. For a polymeric finger, the spring resistance provided by the fingers is determined by the free length of the finger, the width and thickness of the finger, the stiffness of the polymer material the fingers and retainer are manufactured from and embellishments to the fingers such as re-enforcing features such as ribs and variations in section which may range in form from a simple rectangle, oval or simply thicker in the middle. The ends of the fingers are formed so that the circular TX paddle readily displace the fingers as the diameter of the paddle is inserted into the retainer, passing between the fingers. Typical forces to insert the TX paddle into the RX retainer range from 1 to 5 lbs insertion pressure and 1-5 pounds pull to withdraw the TX paddle from the RX retainer.

Instead of a being manufactured from a polymer, the fingers may also be made using spring steel that is mechanically fastened to the RX retainer using but not limited to screws or rivets or that it is encapsulated and anchored within the housing during molding operations. Additional options for the spring fingers are also available. If desired the fingers can be attached to the RX retainer using a sprung hinge design with a spring that applies tension to the finger. The force required to insert or withdraw the TX paddle is determined by the spring rate which may be fixed or adjustable. The springs may be of several formats depending on the mechanical design chosen to operate the finger and may include but not be limited to coil, flat and torsion springs.

Although not an optimal design, as more bulk and higher profile of the retainer is involved, the fingers may be replaced with large displacement spring plungers or other similar sprung mechanical devices. It can be seen from the above the discussion that there are many ways to apply a retention finger or clamp on the RX retainer with a sprung element that secures the TX paddle in place but allows it to be inserted and removed over a high number of cycles, with a predictive amount of force. The previously described versions of the sprung finger are not intended to be limiting.

A feature of the paddle design is that the paddle can be inserted into the retainer using only one bare or gloved hand, with the TX paddle easily inserted into the RX retainer when it is out of the line of sight of the user or otherwise blind to the user. This makes the system user friendly to soldiers, underwater operators, astronauts, or other users that wear gloves and may be in tight confines or have limited line of sight due to equipment or environmental constraints.

The RX retainer may be attached to a user's vest, for example, using external clips or fittings that mate with the vest. Integrated onto the clip may be a fixture to secure and retain the connector on the RX power out cable.

An external electrical power source provides DCV power to the TX drive electronics. The DCV power may be sourced from a vehicle, aircraft or vessel or other facility and can be provided through a conventional physical electro-mechanical connector.

When a user is on-mission, but in a fixed location or stationary, accessible power sources such as solar panels and portable electrical power generators may be used to provide the DC power to the TX drive. In a barrack environment when the warfighter is either wearing the vest or has doffed the vest to which the RX housing is attached, the battery of a vest can be charged at a high rate without removing the battery from the vest by connecting TX drive and paddle system to the DCV output of a power adapter plugged into ACV mains.

The wireless power transmission paddle system can provide from 0-250 W or 0 A to greater than 10 A of charge power at 24V output (400 W with 40 volt systems). As the ability of next generation battery designs such as solid-state lithium-metal or silicone anode batteries allows greater charge rates to be placed into them, then the wireless power output can also be increased accordingly. Ultimately, the upper limit of the transmitted power is not determined by the design of the paddle system but is dependent in the future by power and data manager operating voltages, user system central battery operating voltages, battery capacity, cell chemistry and structure and design that in turn determine maximum charge rates that are allowed to be provided to the user's battery. As battery chemistry evolves and allows faster charge rates, the paddle will also be able to provide increased charge rates.

The wireless alternating current (AC) power received by the RX coil from the TX paddle coil is rectified and converted to direct current (DC) power on a rectification printed circuit board that is contained with the RX electronic circuit housing. The rectified AC power is output as DC power and input to a power and data manager or directly to an independent LI battery charger. Alternately, an SMBus³ smart Li battery charger PCB assembly can be co-located within the RX housing and the output could then be directly connected to a battery that requires charging without the need for other interim devices. The power and data manager provides charge control for the charging of the central battery and also ports power from the battery to the soldier system devices.

The transfer of wireless power, that is the transfer of electrical power across an air gap or space occupied by non-conductive materials, may be facilitated using several wireless power technologies. Within this disclosure the transmission of wireless power is discussed using the application of inductive and magnetic resonance power transfer. For the power paddle, a planar alternating current primary or transmitting (TX) coil couples with a planar alternating current magnetic field secondary or receiving (RX) coil located within the RX housing. The operating distance between the TX and RX coils in the paddle system is between 2-10 mm and is determined by the thickness of housing materials and the interstitial gap between them. Typically, the closer the TX and RX coils are co-located, the higher the power transfer efficiency.

Close coupled inductive power transfer typically utilises but is not limited to frequencies between 20 to 500 kHz, with a typical power TX frequency being around 100 kHz. An example of such a system is one that follows specifications of the Qi Standard⁴. Alternately, loosely coupled planar transmitting and receiving coils and associated drive, control and rectification circuits may employ magnetic resonance with resonant operating frequencies of 6-7 MHz and 13-14 MHz, with a typical operating frequencies of but not limited to 6.78 MHz and 13.56 MHz. Based on the principles of electromagnetic resonance, resonant-based chargers inject an oscillating current into a primary TX coil to create an oscillating electromagnetic field. A secondary RX coil with the same resonant frequency as the TX coil receives power from the electromagnetic field and converts it back into an electrical current that can be used to power and charge devices. An example of a such a system is one that follows specifications of the AirFuel Alliance⁵. Other wireless power transmission protocols may be used that are based on a resonant coupling principle for wireless power transmission.

The wireless power RX rectification circuit to convert the received AC power signal to DC power may be of many circuit topologies but a preferred configuration is one that optimises rectification efficiencies such as a fully synchronous circuit topology.

A functional wireless power paddle system may be built to any of the specifications or standards that provide greater than 10 W of power transmission. Some of the specifications or standards may be limited to the amount of power that can be transmitted in their current revision, however increased power transmission is typically foreseen for all specifications. Alternative wireless power transmission systems may also be designed that do not conform to an existing standard but incorporate for example a Pulse Width Modulated (PWM) TX coil driver and partial or full rectification of the signal received by the RX coil and provide higher power outputs.

Proximity sensing of the RX coil to the TX coil may be used by the wireless power system to prevent inadvertent coupling of power to non target metal bodies. Sensors in the TX coil paddle assembly identify the proximity of the RX coil when the TX paddle has been placed into the RX retainer allowing full wireless power to be transferred. The proximity sensors that could be used but are not limited to, hall effect, NFC and RF protocols such as but not limited to Radio Frequency Identification (RFID), low energy Bluetooth, Internet of Things (IOT), Wi-Fi, ZigBee among other proximity sensing techniques that provide entity identification and discrimination before allowing power transfer between the TX and RX coils.

To obtain optimal power transmission, the RX coil should be no smaller in diameter than 50% of the diameter of the TX coil and no more than 50% bigger than the TX coil. A typical diameter for a TX paddle and RX housing coils is 2.5 inch in diameter as this size works well for both integration of coils into a small volume TX paddle and small volume RX housing while also providing high-rate power transfer. The small size of coil also provides the opportunity for the RX housing to attach and fit into small mounting locations on a military or police tactical vest.

The coil may be wound with all types of wire from single conductor to multiconductor structures, using complex litz wire layups or stacked printed circuit board coil structures. A further alternative is the application of inductive wireless power TX and RX coils constructed as a Multi-layer Self-Resonant Structures (MSRS) where the wire conductive element of an inductive or magnetic resonant coil is replaced with a multilayer insulated foil structure that operates with a nominal operating frequency of 6.78 MHz or other resonant frequencies as may be determined to be practical. The non-conductive substrate may be supporting (i.e. a printed circuit board structure) or a non supporting, non rigid substrate.

The paddle system may also be based upon capacitive coupling between conductive electrodes with signals transmitted and received by alternating the electric field on the electrodes instead of utilising an alternating magnetic field.

Depending on the coil design and the type of wireless power coupling employed, the coil may or may not require a secondary structure such as a ferrite backing or other materials to provide directional wireless power transmission and enhance coupling between the TX and RX coil to improve power transfer efficiencies. The ferrite backing may be a single tile, an array of small tiles, or rigid or flexible ferrite sheet. The design of the primary TX and secondary RX wireless power coils can provide power transfer efficiencies of greater than 93%, with very low stray magnetic flux emitted during due to the close proximity and ferrite backing of the coils. If a ferrite coil backing is employed to reduce stray magnetic flux when the TX and RX coils are coupled and transferring power, the planar ferrite coil backing should overlap the wound coil diameter by a minimum of 5% of the coil diameter.

A unique advantage of non contact power transfer is that there is no loss of power during the rotation of the TX coil relative to the RX coil; that is, rotation of the paddle relative to the retainer.

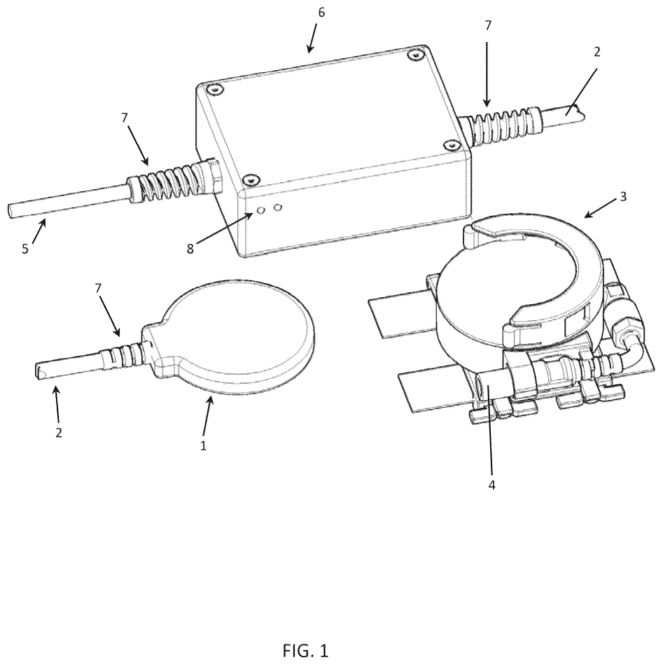

Referring now to the figures, FIG. 1 shows a complete paddle system that includes the TX drive electronics housing 6 and the circular RX housing 3 within which is removably mounted the circular primary TX coil paddle 1. Direct Current (DC) power out is provided via the output connector 4. The TX housing 6 receives power from the vehicle, aircraft, vessel, structure or AC mains converted to DC power via DC input power cable 5 which enters the TX housing 6 with one of many types of threaded waterproof cable entry 7. Indicator LED's 8 provide basic information on the status of supply power and TX power to the TX coil and may include additional indicators to indicate data TX/RX and TX power levels for example. The alternating current TX signal power is provided to the coil 1 via an umbilical cable 2. Wireless power is transfer is provided by inserting the TX coil 1 into the RX housing 3, at which time the TX coil senses it has been placed into the RX housing 3, is energized and transmits AC wireless power to the RX coil contained within the RX housing 3. The low profile of the TX coil paddle 1 is facilitated by the application of a molded cable entry 29.

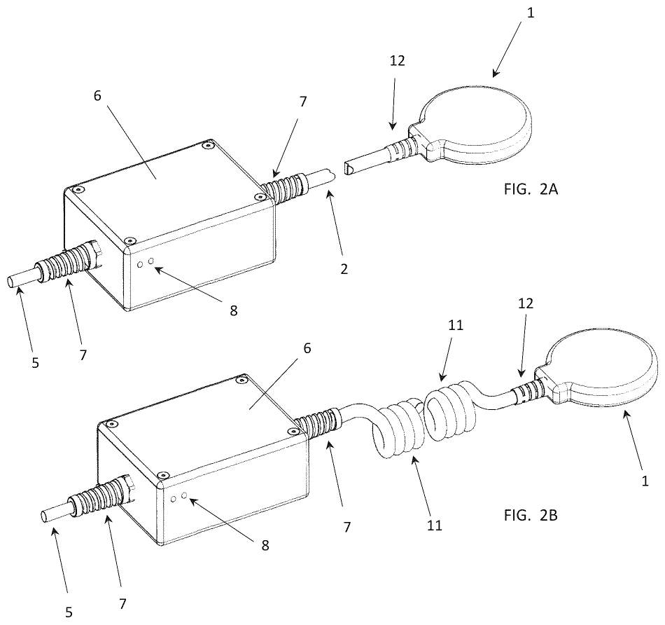

FIGS. 2A and 2B show two variants of TX umbilical cable type that may be implemented on a power and data system. FIG. 2A shows a paddle 1 connected to a drive housing 6 with a straight form extruded umbilical cable 2, that would be compliant and conform to gentle or severe bends along the cable length. FIG. 2B shows a paddle 1 connected to a drive housing 6 TX paddle with a coiled form cable 110 that would be compliant and conform to gentle or severe bends along the cable length.

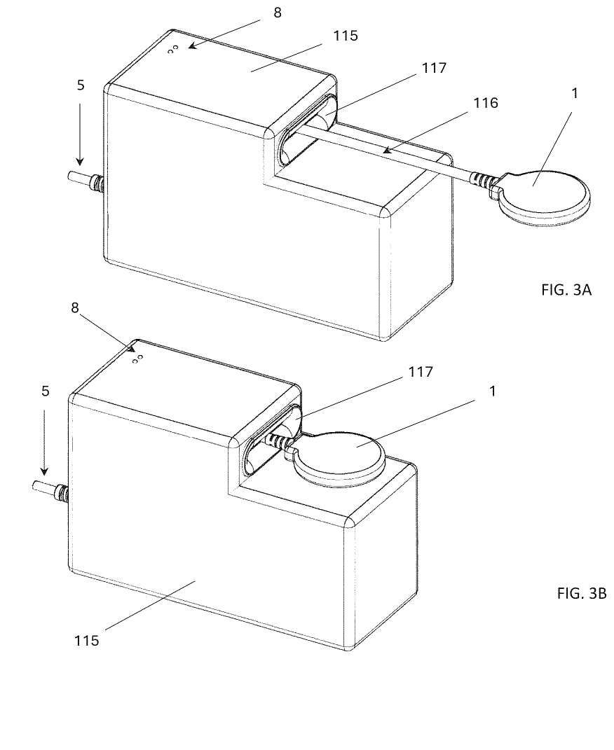

FIGS. 3A and 3B show one of many configurations for a motorised or mechanically sprung, retractable TX umbilical cable and TX paddle using a cable reel housing. The TX cable reel housing 115, contains within it, but not shown, the cable reel and related mechanisms either electrical or mechanical, the TX drive and data circuits, slip ring assembly and internal structures and compartments to house said components. Other components may be incorporated into the cable housing as determined by specific applications. In FIG. 3A the TX cable 116 terminated by the TX paddle 1, is shown partially deployed from the TX cable reel housing 115 through an orifice located on the housing 117. In FIG. 3B the TX umbilical cable (not shown) terminated by the TX paddle 1, is shown in its retracted position on the TX cable reel housing 115. Optionally, the TX umbilical cable may be rewound onto the reel manually, employ a ratchet and spring powered reel for cable retraction, or utilise a controlled electric motor to both deploy and/or retract the umbilical cable.

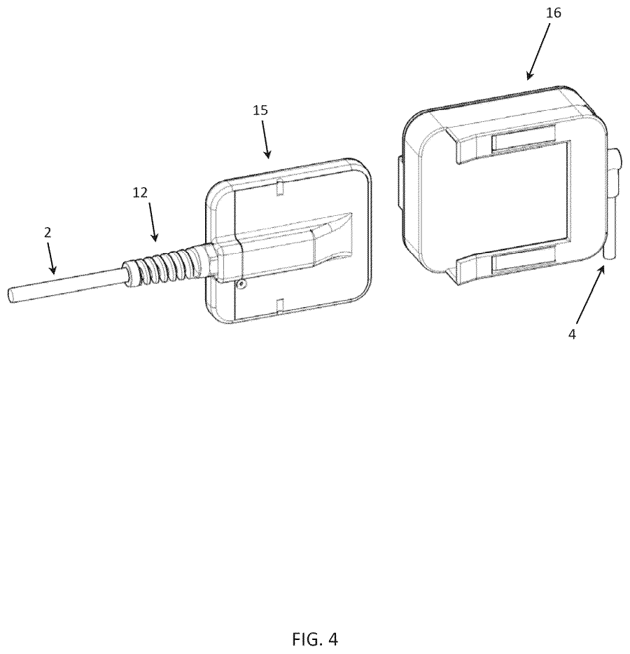

FIG. 4 is an illustration of an early design concept during development of the paddle system showing a TX paddle 15 with a principally square or rectangular shape that is inserted into the RX receiver 16 that has a square or rectangular TX Paddle receptacle designed to accept the rectangular TX paddle 15. There were several design issues of the square paddle that caused it to be rejected as an acceptable design. If any angular force is placed on the TX power cable 2 of the TX coil 15, the TX coil 15 binds within the RX receptacle and is only released with considerable force, often in excess of 10 pounds force of pull. It was very difficult to implement a spring retention design for the TX paddle 15 that provided the required retention force of up to five pounds pull, yet easily allowed the paddle to be inserted within the RX receptacle 16. The paddle had to be perfectly aligned with the opening into the receptacle for the TX paddle to be inserted into it. This sometimes proved difficult when the paddle was inserted blind, with a heavily gloved hand. The paddle could not rotate and was fixed within the receptacle and therefore any movement by the user translated into stresses placed upon the TX paddle cable, which could contribute to premature cable failure.

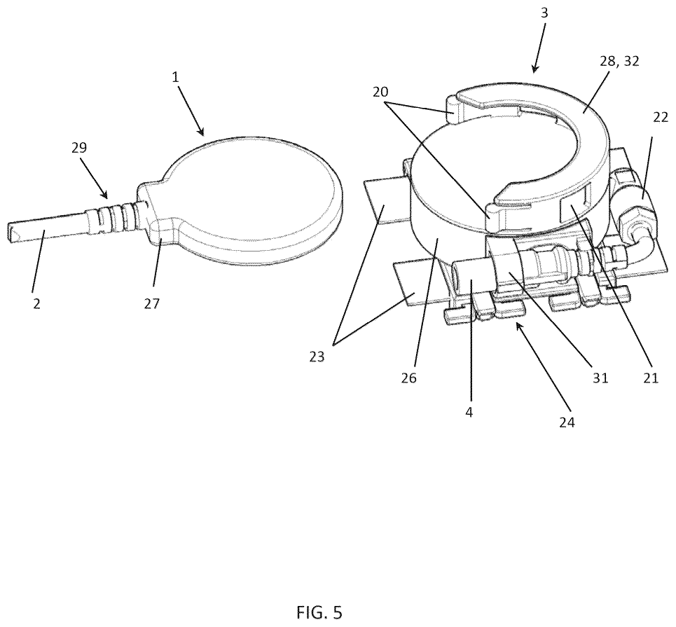

FIG. 5 provides detail of the external features of the circular TX paddle 1 and RX housing 3. Polymer or nonconductive materials are used for both the TX paddle 1 and the paddle retainer 28, as these materials allow unimpeded transmission of the wireless power magnetic field. The electronics housing 26 of the RX housing 3 may be constructed from either a polymeric material or metallic material which may aid in heat dissipation. The principally circular TX paddle 1 has a protruding feature or buttress 27 that serves as a mechanical base or attachment point for the AC power signal cable 2 and a low profile molded type cable entry protrusion 29 to connect with the circular structure of the RX paddle 1. In addition, the coil housing cable protrusion acts as a rotational stop that engages with the circumferential spring fingers 20 to limit its free rotation and act as a pivot point. The range of angular rotation of the paddle can vary between 45 and 160 degrees, however it has been found a 90 degree angle of rotation is the most suitable, as a 90 degree range of rotation is sufficient to provide significant rotation of the paddle within the RX retainer when the user is moving relative to the seat, alleviating stress and strain on the TX cable 2, while also providing sufficient retention of the TX paddle by the spring fingers 20 of the RX retainer. A 90 degrees angle or rotation also provides optimal geometry for the spring fingers 20 to be readily displaced when the TX paddle is inserted into the RX retainer. Once the largest displacement of the fingers caused by the outer diameter of TX paddle 1 passing between the fingers 20 occurs, then the fingers 20 hold the TX paddle 1 within the RX retainer.

The leading edge of the sprung fingers may be formed with a curved contact surface to provide improved displacement of the fingers when the RX paddle 1 is initially engaged against the fingers when being inserted into the RX retainer and is being resisted by the fingers which must be displaced to let the TX paddle 1 be docked within the RX retainer. The sprung fingers 20 may be designed with different levels of displacement and retention force by changing the width, length thickness and formed structure of the polymer finger. Alternately the sprung fingers 20 could be constructed from spring metal and be mechanically attached to the polymer retainer.

A retaining flange 32 is integrated onto the RX retainer 28 to provide containment of the TX paddle within the RX retainer and ensure the TX and RX coils stay proximal to, and advantageously flush against, each other during power transfer. An additional feature of the TX retainer 28 are windows or gaps 21 placed at intervals along the retainer which facilitate the displacement and ejection of any mud, sand, grit, ice and snow or other debris which may otherwise inhibit proper mechanical function of the TX coil 1 with the RX housing 3. Integrated onto the vest clip 24 is a fixture 31 to secure the MightyMouse® soldier system connector or other system connector.

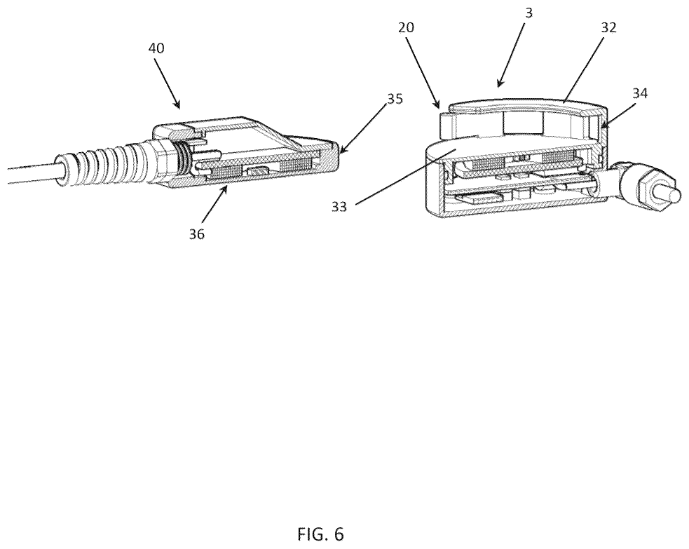

To secure the RX housing to a user's vest such as a soldier or policeman's tactical vest, many types of pocket attachment methods may be used including hook and loop, snap fasteners or spaced horizontal webbing that is known as MOLLE or PAL strapping among other types of pocket attachment methods. For illustration purposes in FIGS. 3A and 3B, the RX housing 3 is shown for attachment to the MOLLE webbing 23 of a vest using appropriate mating attachment clips 24. FIG. 6 shows cross-sections of the TX paddle 40 placed beside a RX housing 3. The paddle 40 is inserted into the housing 3 such that the rim 35 of the paddle 40 is engaged and retained by the flange 32 of the retainer. The face 36 (not shown) of the paddle 40 is then positioned proximal to the face 33 of the housing and is retained in an optimal position for power transfer within the annular U-channel 34 of the housing 3.

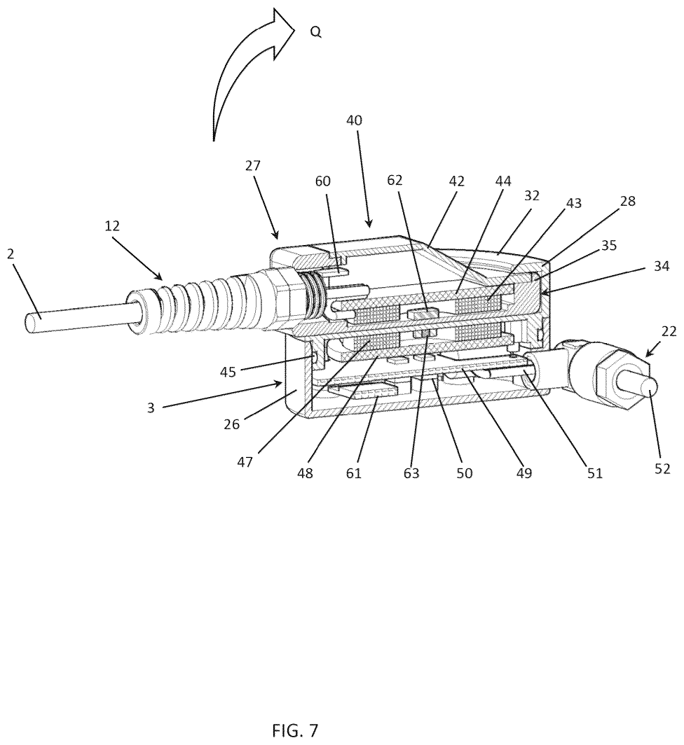

FIG. 7 is a detailed cross section of a TX paddle 40 located within a RX housing 3 showing the internal components of the paddle system. The TX paddle 40 is shown with an optional high profile protrusion 27 to facilitate the threads of a pigtail cable gland 12. The internal volume or void provided by the higher raised profile of the TX paddle 40 cover 42, facilitates connection of the TX drive signal cable 2 to the leads of the RX coil 43. In addition, the void under the higher profile protrusion allows the location of a high-speed data RF transceiver module antenna 60. The TX paddle 40 is constructed from polymeric materials that allow the paddle to be completely sealed from environmental contaminants when fully assembled. When the TX paddle 40 (the TX paddle may be either low or high profile and is referred to generically when regarding electrical or transfer characteristics as these do not change regardless of housing type) is seated within the RX retainer, the rim 35 of the paddle 40 is engaged and retained by the flange 32 of the retainer which with surface 33 forms an annular channel 34. The TX coil 43 is located on a common central axis on the same plane as the RX coil 47 to optimize power transfer efficiency. Ferrite material 44, 48 is placed behind each of the TX coil 43 and RX coil 47 to enhance magnetic field coupling and increase the electrical efficiency of the system by containing and redirecting the magnetic field to the space between the ferrite material and within which the TX and RX coils are located. In turn the ferrite material also reduces any stray magnetic energy that may be created by the system. Due to the nature of an alternating magnetic field, the coils can be rotated relative to each other without any reduction in the power transmitted. As the high-speed data is also provided over a wireless connection there is no loss of power or data when the TX paddle is rotated within the RX retainer. The RX retainer therefore provides release of the TX paddle through 360 degrees of applied force to the TX paddle cable.

The TX coil 43 and RX coil 47 may be of many types of construction. The coil may be wound with all types of insulated magnet wire construction from single conductor to multiconductor structures using complex litz wire layups, or stacked printed circuit board coil structures. Further in the case of a multi-layer self-resonant structure, the coil can be constructed from multiple layers of foil that are layered between a non-conductive substrate or dielectric material. The non-conductive substrate may be supporting (i.e. a printed circuit board structure) or a non-supporting, non-rigid substrate.

The polymeric or non-conductive retention housing 3 is sealed using an O-ring 45 or other type of compliant sealing gasket against the rear housing 26 of the RX housing 3. The rear housing 26 may be constructed from either polymer materials such as any number of plastics or for improved heat dissipation of the internal electronic board assemblies, a conductive material such as aluminum. The RX coil 47 is placed against the backside of the polymer housing so that it is contained and protected from all environmental elements. The complete RX housing is a completely sealed system allowing it to be readily submerged to a 3.3 foot (1 m) depth, and in excess of a 330 feet (100 m) with additional design detail. It is impervious to many environmental hazards that would be experienced by the user.

The rear housing 26 of the RX housing 3 (shown without vest attachment clips for clarity) contains the RX rectification circuit 49 used to convert the received AC to DC. The circuit may be of many circuit topologies, but a preferred configuration is one that optimizes rectification efficiencies such as a fully synchronous circuit topology. In addition, the rectification circuit, additional circuit components may be used for the system to be compliant with QI or AirFuel Alliance specifications and allow communication between the TX and RX circuits to ensure both safe and optimal operation. Alternate methods of proximity sensing of the RX coil to the TX coil may be used by the wireless power system to prevent inadvertent coupling of power to none target metal bodies.

Sensors such as a hall effect sensor(s) 62 in the TX paddle 40 are triggered by the proximity of the RX coil trigger magnet(s) 63. Other sensor technologies such as but not limited to NFC and RF protocols, such as Radio Frequency Identification (RFID), low energy Bluetooth, Internet of Things (IOT), Wi-Fi, ZigBee among other proximity sensing techniques that provide entity identification and discrimination before allowing power transfer from the TX coil to the RX coil.

Thermal transfer compounds 50 allow the conduction of heat from the rectification circuit board 49 to the rear housing 26. The received AC power signal from the RX coil is output from the rectification board as a DC power signal and is ported to the RX housing output cable 51. The DC output power is then passed to a multi conductor cable 52 that also contains the data signals from the RF transceiver module 61 and which passes through the sealed output cable gland 22 to the soldier system or other external power and data managers.

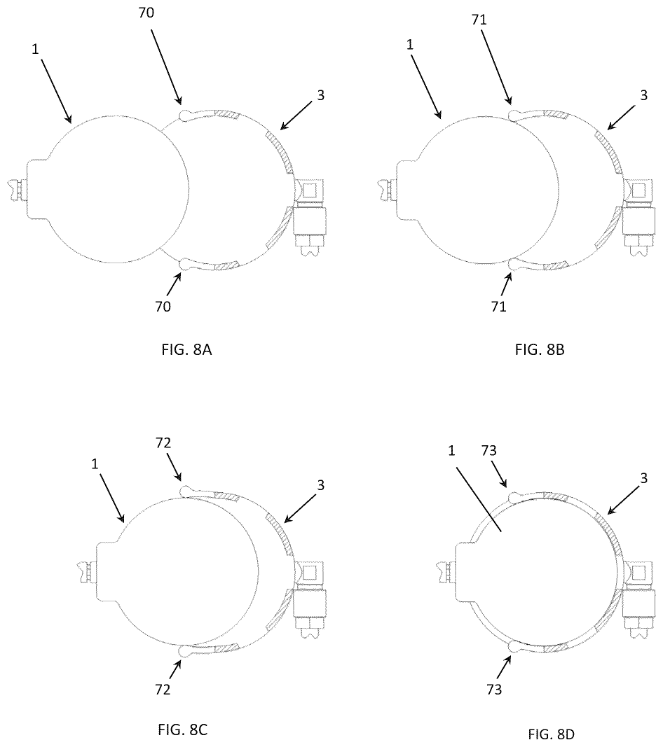

FIGS. 8A to 8D illustrate the displacement mechanics of the TX paddle circumferential retention fingers. FIG. 8A shows the TX paddle 1 located in a position prior to engagement with the RX retainer, with the sprung retention fingers 70 in their home position. FIG. 8B shows the TX paddle 1 as it engages the sprung fingers 71 with first contact of the TX paddle at the formed edge of the sprung fingers 71. The formed edge of the fingers 71 allows the fingers to ride over the outer diameter of the paddle as the paddle is inserted into the retainer. FIG. 8C shows the TX paddle 1 located in a position with the sprung retention fingers 72 at their maximum displacement as the outer diameter of the TX paddle passes between the fingers. FIG. 8D shows the TX paddle 1 located completely with the retainer structure of the RX housing 3 with the sprung retention fingers 73 in their home position and providing spring resistance to the withdrawal of the TX paddle 1. The amount of spring resistance provided by the fingers is determined by the free length of the finger, the width and thickness of the finger, the stiffness of the polymer material the fingers and retainer are manufactured from and embellishments to the fingers such as re-enforcing features such as ribs and variations in section which may range in form from a simple rectangle, oval or simply thicker in the middle.

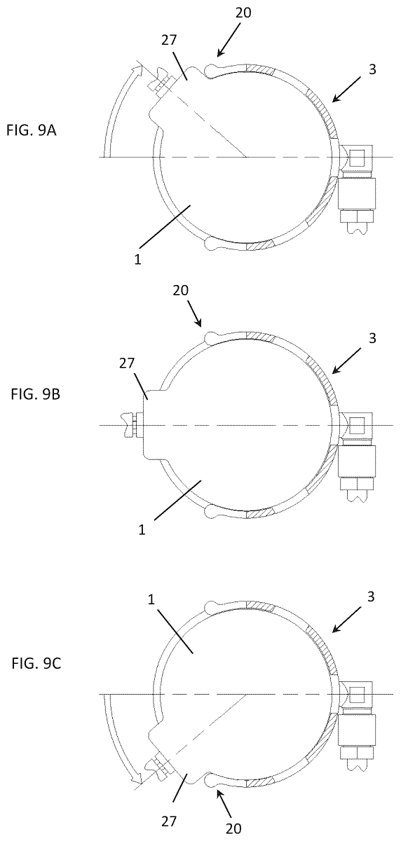

FIGS. 9A, 9B and 9C show the angular rotation of the TX paddle 1 with the RX retainer. In FIG. 9A the paddle is rotated through 45 degrees from its central location, with the TX paddle cable entry protrusion 27 up against the sprung finger 20 and acting as a rotation stop. FIG. 9B shows the TX paddle 1 in its central location with the RX housing 3 retainer structure. FIG. 9C shows the paddle rotated through minus 45 degrees from its central location, with the TX paddle cable entry protrusion 27 against the sprung finger 20 and acting as a rotation stop. The total range of rotation shown in FIGS. 9A to 9C for the TX paddle is 90 degrees. The range of rotation also provides reduction of stress and fatigue on the cable assembly of the TX paddle allowing it to move and rotate when the user moves position within their seat. The square or rectangular paddle prevented rotation and exacerbated strain and failure of the cable where it entered the TX paddle.

In addition, the circular shape of the TX paddle allows the paddle to be inserted into the RX retainer with a wide 120 degree arc angle of approach, defined as the radial arc, relative to the center of the paddle surface, swept out by a radius moving 120 degrees over the paddle surface. The 120 degree arc coincides with the wide gap into the retainer. Thus, the TX paddle does not have to be carefully aligned with the central axis of the RX retainer. This latitude of TX paddle engagement within the RX retainer is what allows the TX paddle to be easily inserted into the RX retainer blind and with a heavily gloved hand. This shape compares very favorably against the square TX paddle design, which has a very low tolerance of angular approach and can only be inserted into the square RX receptacle if it is perfectly aligned along the central axis of the rectangular RX receptacle. In tight confines or when wearing overly restrictive equipment, the 120 degree engagement arc greatly reduces the effort required to align and insert the cylindrical TX paddle into the cylindrical RX retainer.

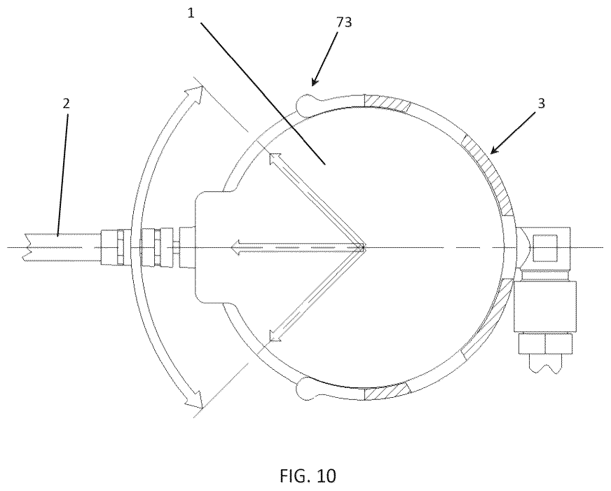

FIG. 10 shows how the TX paddle 1 can be removed from the RX retainer while in any angular orientation within the 90 degree arc of free paddle rotation that is provided when the TX paddle 1 is docked in the RX retainer. This would be considered removal of the TX paddle 1 from the RX retainer during normal operation, when the paddle is removed manually by the user or if he simply moves away from the TX drive housing making the TX paddle cable 2 go taut and causing the paddle to self-eject or auto separate from the retainer.

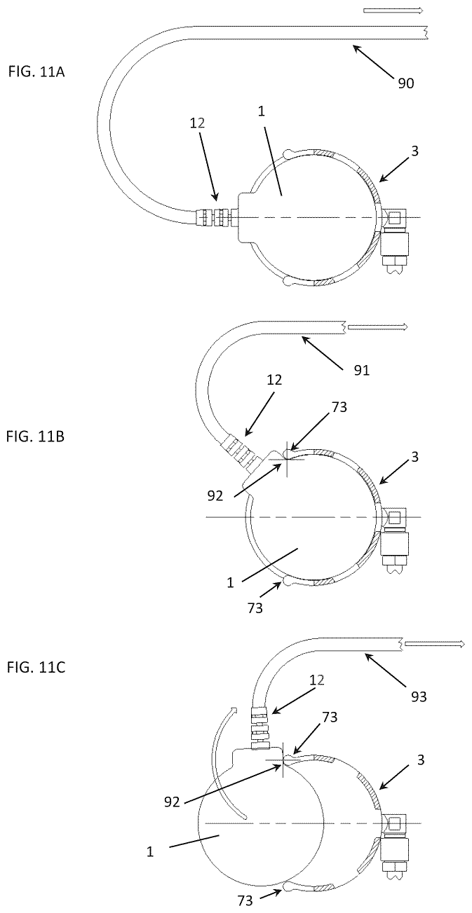

FIGS. 11A to 11C illustrate a force being applied to the TX cable in a direction that is 180 degrees opposed to the gap or aperture of the upper side of the RX retainer. Combining both upper and lower direction of cable forces, the RX retainer therefore provides release of the TX paddle through 360 degrees of applied force to the TX paddle cable. This event may occur in an emergency or accident or other equipment usage scenario where it is critical the TX paddle not hang up or bind within the RX retainer and impede either the emergency egress from a vehicle of the user or in the application of other equipment, the separation of the TX paddle from the RX retainer. FIG. 11A represents the start of the umbilical cable 90 being pulled away from the RX retainer gap, with the TX paddle 1 positioned in-line with the central axis of the gap. FIG. 11B shows that as a force continues to be exerted on the cable 90, the TX paddle 1 rotates within the retainer until the TX paddle 1 cable entry engages with a contact point 92 at the tip of either sprung finger 73. In FIG. 11C as the force on the cable 93 continues to be applied, the contact point 92 between the TX paddle 1 and the retainer finger 73 causes the TX paddle 1 to rotate out and free of the RX retainer without any binding or impediment to the release of the TX paddle 1 from the RX retainer.

The umbilical cable gland entry into the paddle may be a short waterproof cable gland or advantageously it may be a cable gland with integral strain relief. The strain relief may be a flexible extrusion such as a flexible tube or it may be a complex shape such as a pigtail strain relief 12. It has been found that the length of the strain relief should be between 50-100% of the paddle diameter. The combination of the strain relief length coupled with its resilience assist in the sprung release of the paddle from the retainer channel fingers allowing the paddle to be ‘popped’ out of the retainer.

Also shown in FIG. 7, if a force Q, which may range from 0-90 degrees from the plane of the paddle, is applied to the paddle umbilical cable, the paddle will still release from an RX housing that is attached to an operator's vest. In slow motion video studies, when a short substantial force is applied to the cable in the direction Q, the paddle will rotate within the retainer until a finger is encountered, causing the paddle to rotate and pop out of the retainer. When in-plane forces are applied to the umbilical, the length and resilience of the pigtail cable strain relief contribute to this action.

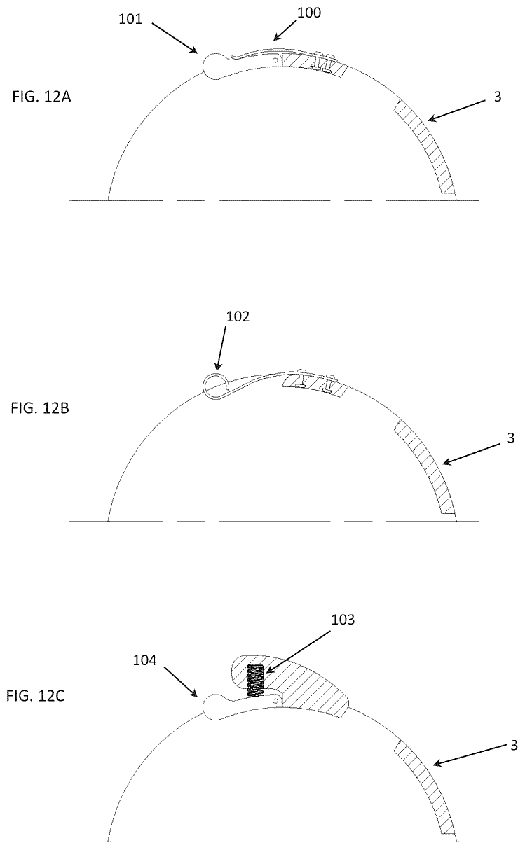

FIGS. 12A to 12C show three alternate configurations of providing a sprung finger on the RX retainer. FIG. 12A shows a hinged finger 101 that is sprung or loaded by a leaf spring 100. Movement of the finger 101 towards the center of the RX retainer is prevented by stops (not shown) incorporated onto the finger. The leaf spring 100 can be attached to the RX retainer using mechanical fasteners such as but not limited to screws or rivets or can be held captive by molding the leaf spring 100 into the RX retainer. FIG. 12B shows how a leaf spring 102 by itself could be used as the sprung finger. The leaf spring 102 can be attached to the RX retainer using mechanical fasteners such as but not limited to screws or rivets or can be held captive by molding the leaf spring 102 into the RX retainer. FIG. 12C shows a further option whereby a coil spring 103 is embedded within the RX retainer 3 to provide spring resistance to a hinged finger 104. Movement of the finger 104 towards the center of the RX retainer is prevented by stops (not shown) incorporated onto the finger. The three examples provided are not intended to be limiting and other methods of providing a sprung finger on the RX retainer may be implemented.

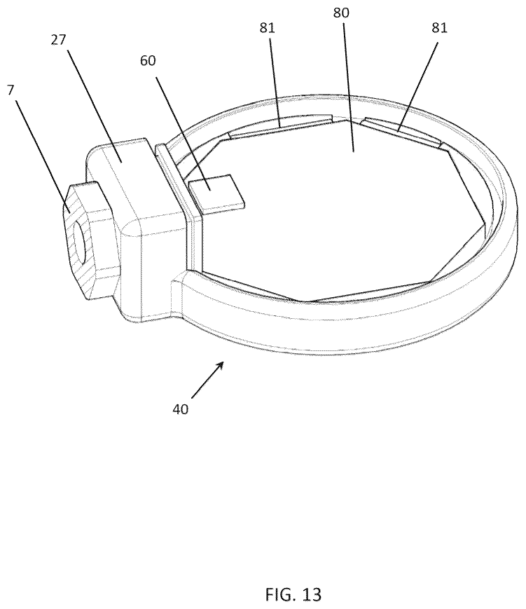

FIG. 13 shows the TX paddle 40 with the cover removed to show alternate locations and types of radio transceiver module antennas located within the paddle. A planar PCB type antenna 60 may be used as an antenna or alternately a cylindrical type co-axial antenna 81, as two examples of the many types of antennas that may be used. Also shown, is the TX paddle coil ferrite backing 80 with an octagonal shape. The ferrite material may be any geometrical shape, although circular is preferred, that allows the ferrite material to fit within the dimensional confines of the circular TX paddle housing. Other geometries of TX paddle and RX retainer could be utilised based on hexagon, or octagon for example all of which would be non-circular as a ferrite but can be incorporated into a circular structure.

### REFERENCED SPECIFICATIONS, STANDARDS AND TRADEMARKS

1. MIL-PRF-32383/4. Battery, Rechargeable, Sealed, Conformal Wearable Battery (CWB), BB-2525. No enabled versions. United States Department of Defense, 2022. Retrieved from: Standards Central https://publishers.standardstech.com/content/military-dod-mil-prf-32383-4. Accessed: 2022-04-12.
2. SMBus configuration protocols as described in: System Management Bus (SMBus) Specification, version 3.1. 19-Mar-2018. http://smbus.org/specs/3.
3. IP68 as defined in: International Electrical Commission (IEC) 60529.Degrees of Protection Provided by Enclosures (IP Code), Edition 2.1, 2001-02.
4. Qi Standard, Wireless Power Consortium. https://www.wirelesspowerconsortium.com
5. AirFuel Alliance AFA TS-0010-A V2.00, AirFuel Alliance Resonant Baseline System Specification (BSS). July 25, 2018 https://airfuel.org
6. MightyMouse™-Glenair Inc, Glendale, CA, US
7. Bluetooth®-Registered Trademark Blue Tooth Special Users Group
8. Wi-Fi®-Registered Trademark Wi-Fi Alliance
9. Zig-Bee®-Registered Trademark Connectivity Standards Alliance
10. Z-Wave®-Registered Trademark Z-Wave Alliance

What is claimed is:

1. A paddle system for wireless power transfer comprising:
a paddle retainer on a first surface of a receiver coil housing,
a paddle having a transmitter coil housing, the transmitter coil housing having a first planar surface, wherein the first planar surface of the transmitter coil housing has a circular perimeter, wherein the paddle has a circular rim coinciding with the circular perimeter, the rim having a first thickness,
wherein the paddle retainer includes at least segments of an annular channel around a perimeter of the first surface of the receiver coil housing wherein the annular channel is adapted to mate in sliding relation with the rim of the paddle when the first planar surface of the transmitter coil housing is parallel with, and immediately adjacent to, the first planar surface of the receiver coil housing,
the annular channel having a gap through which the paddle is inserted so as to releasably mate with the annular channel,
at least one resilient clamp mounted at the gap of the annular channel and arranged to resiliently urge the paddle into mating engagement with the annular channel and to resiliently hold the rim of the paddle in the annular channel once the paddle has been inserted through the gap so as to mate the rim of the paddle with the annular channel.

2. The paddle system of claim 1 wherein the at least one resilient clamp is a pair of resilient clamps, and where in the gap in the annular channel has first and second edges, and wherein one clamp of the pair of resilient clamps is mounted on each of the first and second edges.

3. The paddle system of claim 2 wherein the pair of resilient clamps include resilient clamps chosen from the group comprising: sprung fingers, spring arms, rigid arms biased by a spring, any combination of these.

4. The paddle system of claim 3 wherein each of the resilient clamps of the pair of resilient clamps are elongate, having a base end and an opposite free end, and wherein the base end of a first clamp of the pair of resilient clamps is mounted to the first edge of the gap into the annular channel so as to position the free end of the first clamp over, so as to partly occlude the gap into the annular channel, and wherein the base end of a second clamp of the pair of resilient clamps is mounted to the second edge of the gap into the annular channel so as to position the free end of the second clamp over, so as to partly occlude the gap into the annular channel, and wherein the first and second clamps are opposed-facing.

5. The paddle system of claim 3 wherein the gap into the annular channel spans 120 degrees arc relative to a center of curvature of the annular channel.

6. The paddle system of claim 5 wherein the annular channel is sized to snugly accept the rim of the paddle in sliding mating therein contiguously around an entire length of the annular channel.

7. The paddle system of claim 5 wherein the annular channel has drainage apertures formed therein.

8. The paddle system of claim 5 wherein the annular channel is segmented to facilitate drainage of fluid from the annular channel.

9. The paddle system of claim 5 wherein the segments of the annular channel are chosen from the group comprising multiple fingers, projections or clips arranged around the periphery of the retainer and adapted to retain and secure the paddle within the retainer.

10. The paddle system of claim 9 wherein a paddle umbilical cable is integrally formed with and electrically coupled to a TX drive housing within the paddle.

11. The paddle system of claim 10 wherein the umbilical cable further includes, so as to pass through, a resilient cable strain relief attached to the paddle, and wherein the strain relief is adapted to facilitate ejection of the paddle from the paddle retainer.

12. The paddle system of claim 11 wherein the paddle retainer is such that the paddle is ejected from the annular channel when a tension force is applied gap so as to pull the paddle out of the plane of the paddle and receiver housing.

13. The paddle system of claim 12 wherein the TX and RX coils are chosen from the group comprising wound with single conductor wire, multiconductor wire structures, litz wire structures or stacked printed circuit board coil structures.

14. The paddle system of claim 13 wherein the coil is a multi-layer self-resonant structure, where the coil is constructed from multiple layers of foil that are layered between a non-conductive substrate or dielectric material.

15. The paddle system of claim 14 wherein the gap is adapted so that the paddle is rotatable through an arc of 90 degrees while retained within the annular channel of the retainer.

16. The paddle system of claim 1, wherein the paddle system is adapted to be used in terrestrial vehicles, fixed structures on land, submersible vehicles, aeronautical vehicles, or space vehicles.

17. The paddle system of claim 16, wherein the paddle system is adapted to transfer electrical power and data between the vehicles or fixed structures to human operators or to electronic devices and equipment.
